(19) United States
(12) Patent Application Publication
(10) Pub. No.: US 2012/0018880 A1
(43) Pub. Date: Jan. 26, 2012

(54) SEMICONDUCTOR STRUCTURE AND MANUFACTURING METHOD THEREOF

(76) Inventors: Kun-Tai Wu, Zhubei City (TW); Ching-San Lin, Wufeng Township (TW); Owen Wang, Zhubei City (TW)

(21) Appl. No.: 13/171,906

(22) Filed: Jun. 29, 2011

(30) Foreign Application Priority Data
Jul. 26, 2010 (TW) 099124571

(51) Int. Cl. H01L 23/498; H01L 21/50

(52) U.S. Cl. 257/737; 438/107; 438/666; 257/E23.068; 257/E21.499

(57) ABSTRACT

A semiconductor structure and a manufacture method thereof are disclosed. The semiconductor structure includes a semiconductor wafer having a plurality of semiconductor device dies, wherein each of the semiconductor device dies includes a die body, a metal wiring layer, a bump, and a metal layer. The metal wiring layer is formed on the die body while the bump is formed on the metal wiring layer during the semiconductor front-end-of-line (FEOL) process and protrudes from the die body. The metal layer is disposed on one side of the bump opposite to the metal wiring layer, wherein the activity of the metal layer is smaller than the activity of the bump. In this way, the semiconductor structure of the present invention is easy to be manufactured and the manufacture cost is also reduced.

### BACKGROUND OF THE INVENTION

1. Field of the Invention

This invention relates to a semiconductor structure and a manufacture method thereof; specifically, the present invention relates to a semiconductor structure including a bump formed during semiconductor front-end-of-line (FEOL) processes and the manufacture method thereof.

2. Description of the Prior Art

Wafer is a silicon substrate used to manufacture semiconductor integrated circuits. A plurality of functional dies are formed on the wafer through a series of processes including deposition, photolithography, etching, etc., wherein each of the dies is then tested, cut, and packaged into a plurality of integrated circuit chips.

FIG. 1A is a schematic view of a conventional semiconductor wafer and FIG. 1B is a schematic view of a semiconductor device die. As FIG. 1A shows, a plurality of semiconductor device dies 2 are formed on the wafer 1. As FIG. 1B shows, each of the semiconductor device dies 2 includes a die body 3, a metal wiring layer 4, and a bump 5. The metal wiring layer 4 is formed on the die body 2. The bump 5 is formed on the metal wiring layer 4 and protrudes from the die body 3 so that the bump 5 can be electrically connected to other devices such as other metal trace on the glass substrate. In general, the metal wiring layer 4 is formed during semiconductor FEOL processes in the wafer fabs while the bump 5 is formed during the wafer bumping process of the semiconductor back-end-of-line (BEOL) in the assembly and package factories. In order to save manufacturing costs, the metal wiring layer 4 is made of cheap metals such as aluminum or copper. On the other hand, in order to avoid oxidation of the bump 5 and poor contact between the bump 5 and other devices, metals with lower activity such as gold is used to form the bump 5.

However, although gold can effectively protect the bump 5 from oxidation, the use of gold during the semiconductor back-end-of-line results in high manufacturing costs and complicated processes and therefore is not ideal in the current semiconductor processes requiring high efficiency and low costs.

### SUMMARY OF THE INVENTION

It is an objective of the present invention to provide a semiconductor structure and a manufacture method thereof to form a bump on a wafer during the semiconductor FEOL processes to simplify the semiconductor process and reduce the manufacturing cost.

It is another objective of the present invention to provide a semiconductor structure and a manufacture method thereof to incorporate the process of forming bumps into the semiconductor FEOL processes and use metals commonly used in the semiconductor FEOL processes such as aluminum and copper to integrate the semiconductor manufacture process.

The semiconductor structure of the present invention includes a semiconductor wafer having a plurality of semiconductor device dies, wherein each of the semiconductor device dies includes a die body, a metal wiring layer, a bump, and a metal layer. The metal wiring layer is formed on the die body. The bump is formed on the metal wiring layer during a semiconductor FEOL process and protrudes from the die body. The metal layer is disposed on one side of the bump opposite to the metal wiring layer, wherein the activity of the metal layer is smaller than the activity of the bump. The bump of the semiconductor structure of the present invention is formed during the semiconductor FEOL process. In this way, the semiconductor structure of the present invention, compared with conventional semiconductor structures, is easy to be manufactured and has lower manufacture cost.

The method of manufacturing the semiconductor structure of the present invention includes steps of providing a semiconductor wafer and forming a plurality of semiconductor device dies on the wafer, wherein each of the semiconductor device dies includes a die body. The method further includes forming a metal wiring layer on the die body, forming a bump on the metal wiring layer during the semiconductor FEOL processes so that the bump protrudes from the die body, disposing a metal layer on one side of the bump opposite to the metal wiring layer, wherein the activity of the metal layer is smaller than the activity of the bump. Since the bump of the present invention is formed during a semiconductor FEOL process in the wafer fabs, the method of forming bumps is simpler than the conventional methods of forming bumps during the semiconductor back-end-of-line in the assembly and package factories and the costs of manufacturing the semiconductor structure are also reduced.

### BRIEF DESCRIPTION OF THE DRAWINGS

FIG. 1A is a schematic view of a conventional semiconductor wafer;

FIG. 1B is a schematic view of the semiconductor device die of the conventional semiconductor wafer illustrated in FIG. 1A;

FIG. 2 is a schematic view of the semiconductor device die of the present invention;

FIG. 3 is a schematic view of the semiconductor device die in another embodiment of the present invention;

FIG. 4 is a schematic view of the semiconductor device die illustrated in FIG. 3 in use;

FIG. 5A is a method of manufacturing the semiconductor structure of the present invention;

FIG. 5B is a schematic view illustrating the method of forming a bump of the semiconductor structure illustrated in FIG. 5A;

FIG. 6 is a schematic view of the method of manufacturing the semiconductor structure of another embodiment of the present invention;

FIG. 7A is a schematic view illustrating the method of manufacturing the semiconductor structure of another embodiment of the present invention; and

FIG. 7B is a schematic view illustrating a step of forming an insulating layer illustrated in FIG. 7A.

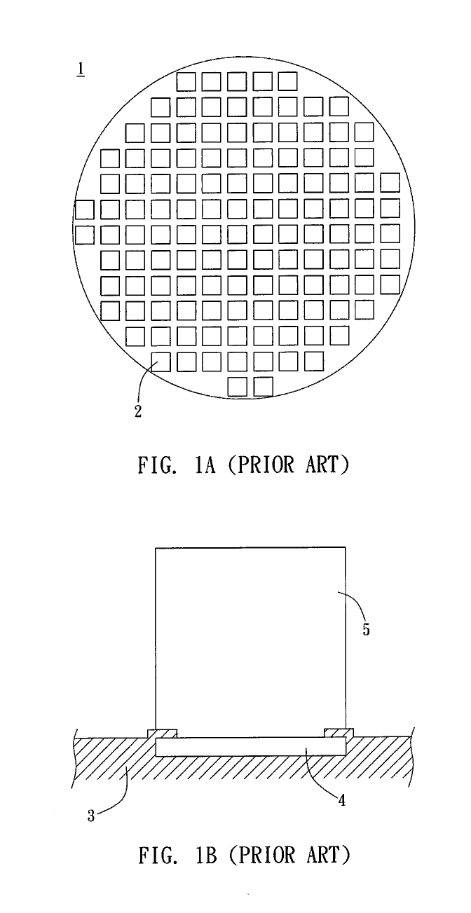

### DETAILED DESCRIPTION OF THE PREFERRED EMBODIMENT

The present invention provides a semiconductor structure and a manufacture method thereof. In a more preferred embodiment, the semiconductor structure of the present invention and the manufacture method thereof can be used in any semiconductor related devices needing bump structures (such as integrated circuits of semiconductor devices or driving circuits of liquid crystal display) and manufacture processes thereof.

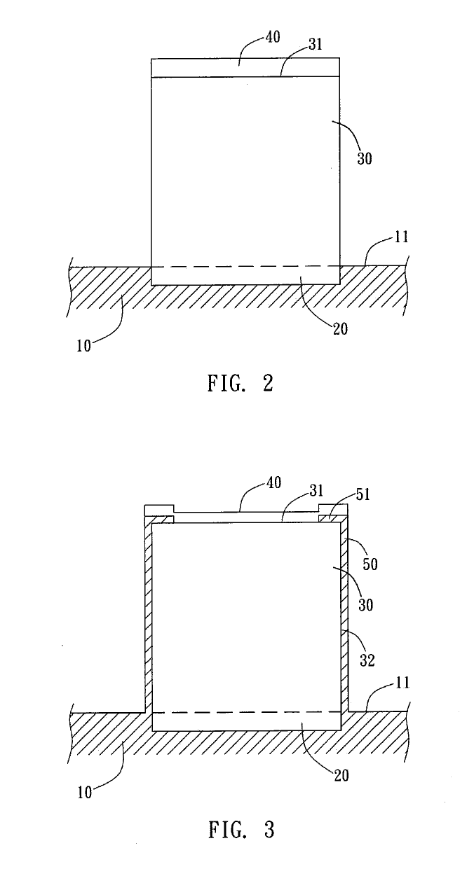

The semiconductor structure of the present invention includes a semiconductor wafer having a plurality of semiconductor device dies. The semiconductor device dies are preferably formed by semiconductor processes such as repetitive deposition, photolithography, etching, etc. FIG. 2 is a schematic view illustrating one of the semiconductor device dies of the semiconductor wafer in one embodiment of the present invention. As FIG. 2 shows, the semiconductor device die includes a die body 10, a metal wiring layer 20, a bump 30, and a metal layer 40. The metal wiring layer 20 is formed on the die body 10 and can be one of many metal wiring layers of the die body 10, wherein the metal wiring layer 20 is normally located on the top of the die body 10 for making contact with other devices. The metal wiring layer 20 is preferably formed by semiconductor processes such as deposition, photolithography, etching, etc. that are commonly known in the art. In the present embodiment, the metal wiring layer 20 is made of aluminum but can be made of other metals such as copper or alloys in other embodiments.

The bump 30 is formed on the metal wiring layer 20 and protrudes from a surface 11 of the die body 10, wherein the bump 30 and the metal wiring layer 20 are formed during the semiconductor FEOL process. In other words, the bump 30 is formed using pre-existing wafer manufacturing equipments in the semiconductor wafer fabs. The bump 30 is preferably formed by semiconductor processes such as deposition, photolithography, and etching. In the present embodiment, the metal wiring layer 20 and the bump 30 are both made of the same material such as aluminum, but are not limited thereto. In different embodiments, the metal wiring layer 20 and the bump 30 can be made of different materials. In addition, the bump 30 can also be made of other metals such as copper. In one embodiment of the present invention, the metal wiring layer 20 and the bump 30 are integrated into a single structure made of one metal material layer using deposition, photolithography, and etching. In a different embodiment of the present invention, the metal wiring layer 20 and the bump 30 are separate metal layers made by semiconductor processes including deposition, photolithography, etching, etc.

The metal layer 40 is disposed on one side 31 of the bump 30 opposite to the metal wiring layer 20, wherein the activity of the metal layer 40 is smaller than the activity of the bump 30. The metal layer 40 is preferably formed by semiconductor processes or other processes such as electroplating. In the present embodiment, the metal layer 40 is made of gold, but is not limited thereto. In different embodiments, the metal layer 40 can be made of other inert metals.

The bump 30 of the semiconductor structure of the present invention is formed during the semiconductor FEOL processes and made of materials commonly used in the semiconductor FEOL processes such as copper or aluminum which is more cost effective than gold. In this way, the semiconductor structure of the present invention has the advantages of reduced manufacturing costs and compatible with current process flow. Furthermore, the metal layer 40 is made of gold with higher conductivity and lower activity and formed on the bump 30 made of aluminum or copper. In this way, the above-mentioned structure strengthens the bonding effect between the bump 30 and other devices while preventing the bump 30 from degradation caused by oxidation.

FIG. 3 is a schematic view of the semiconductor device die in another embodiment of the present invention. As FIG. 3 shows, the semiconductor device die further includes an insulating layer 50 disposed on a sidewall 32 of the bump 30 and surrounding the bump 30 in order to provide the bump 30 with insulation and thus protection against oxidation. In a more preferred embodiment, the insulating layer 50 extends toward the centre of the top of the bump 30 and covers a portion of the side 31. A covering portion 51 of the insulating layer 50 is disposed between the bump 30 and the metal layer 40 in order to ensure that the connection between the bump 30 and the metal layer 40 are not exposed and therefore not subject to oxidation. However, in different embodiments, the covering portion 51 can be omitted, i.e. the insulating layer 50 is disposed only on the sidewall 32. The insulating layer 50 is preferably formed by semiconductor FEOL processes such as deposition, photolithography, and etching. The insulating layer 50 can be made of insulating materials such as silicon nitride, silicon oxide, silicon oxynitride and has noticeable thickness in order to provide the bump 30 with insulation and thus protection from reaction such as oxidation.

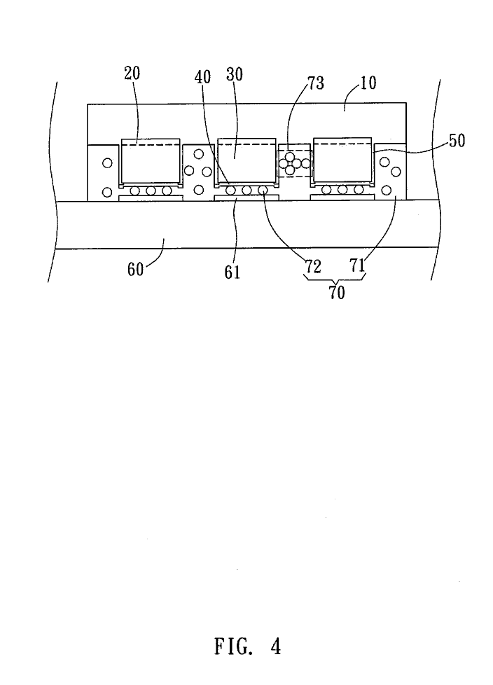

FIG. 4 is a schematic view of the semiconductor device dies illustrated in FIG. 3 in use. As FIG. 4 shows, the substrate 60 includes a plurality of spaced conductive films 61, wherein each one of the bumps 30 corresponds to one conductive film 61. A conductive layer 70 is connected to both the substrate 60 and the die body 10. The conductive layer 70 includes an insulating adhesive 71 and conductive particles 72, wherein the metal layer 40 on the bump 30 is electrically connected to the conductive film layer 61 via the conductive particles 72. As FIG. 4 shows, even if conductive particles 72 between two bumps 30 are aligned to form a conduction path 73, the insulation provided by the insulating layer 50 prevents the adjacent bumps 30 from short-circuit. In a more preferred embodiment, the substrate 60 is made of glass, the conductive film 61 is a metal electrode layer formed on the substrate 60, and the conductive layer 70 can be made of anisotropic conductive film (ACF), but are not limited thereto. In different embodiments, the substrate 60, the conductive film 61, and the conductive layer 70 can also be made of other materials.

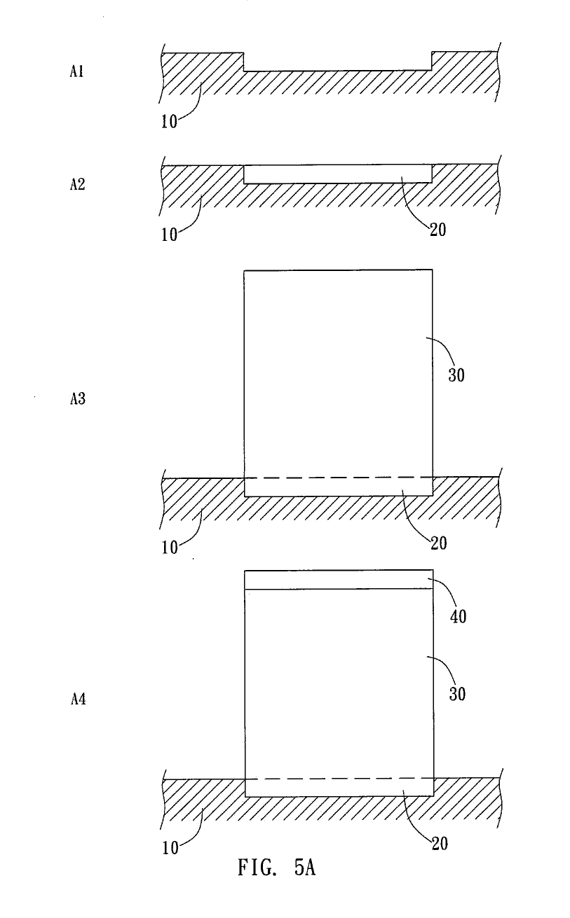

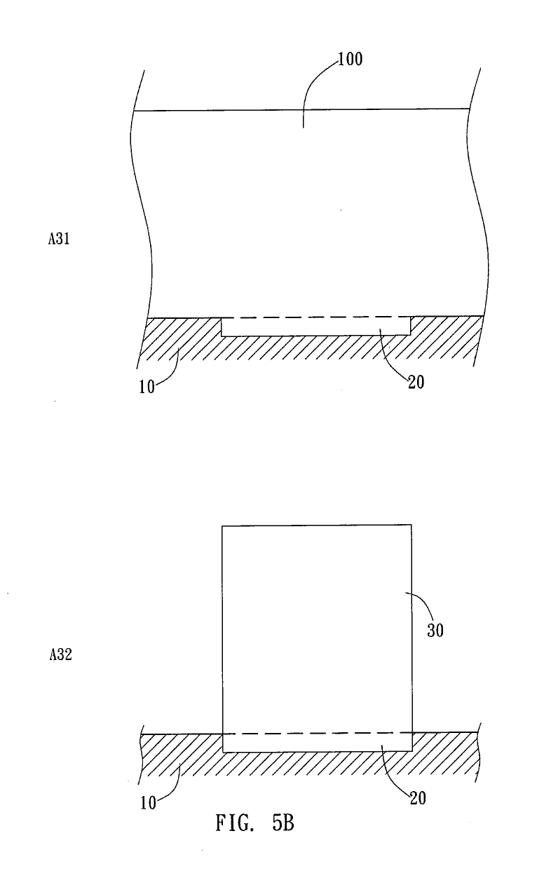

FIG. 5A is a schematic view illustrating a method of manufacturing the semiconductor structure. As FIG. 5A shows, the method includes step Al of forming a plurality of semiconductor device dies on a semiconductor wafer during the wafer process, wherein each of the semiconductor device die includes a die body 10. Specifically speaking, the semiconductor device die 10 is formed by semiconductor processes such as repetitive deposition, photolithography, etching, etc. to form a semiconductor device with pre-defined functions. The semiconductor device can be an integrated circuit device having a bump structure and electrically connected to other devices such as a semiconductor integrated circuit or a driving circuit of a liquid crystal display. Step A2 includes forming a metal wiring layer 20 on the die body 10. Specifically speaking, the metal wiring layer 20 is formed on, the die body 10 and can be formed as one of many metal wiring layers. Normally, the metal wiring layer 20 is the topmost/outmost metal layer on the semiconductor device die. The metal wiring layer 20 is preferably formed by semiconductor FEOL processes such as deposition, photolithography, and etching. For instance, step A2 of forming the metal wiring layer 20 includes defining the location of the metal wiring layer on each semiconductor device die of the semiconductor wafer using lithography method. Afterward a blanket metal layer is deposited on the defined location and then etched and polished to form the metal wiring layer 20 on the die body 10. As FIG. 5A shows, in the present embodiment, the metal wiring layer 20 is made of aluminum, but is not limited thereto. In different embodiments, the metal wiring layer 20 can be made of other metal materials such as copper.

Step A3 uses semiconductor FEOL processes to form a bump 30 on the metal wiring layer 20, wherein the bump 30 protrudes from the die body 10.

FIG. 5B is a schematic view illustrating step A3 of forming the bump 30 on the metal wiring layer 20 which is illustrated in FIG. 5A. In the present embodiment, as FIG. 5B shows, step A3 of forming the bump 30 includes step A31 of depositing a metal material layer 100 on the metal wiring layer 20, wherein the activity of the metal material layer 100 is greater than the activity of gold. Specifically speaking, the metal material layer 100 covers the surfaces of the die bodies 10 of the semiconductor wafer and the metal wiring layer 20. Step A32 includes processing the metal wiring layer 100 using photolithography method and etching method in order to form the bump 20 on the metal wiring layer 20. Specifically speaking, the bump 30 is formed on the metal wiring layer 20 and protrudes from the surface of the die body 10. In the present embodiment, the metal wiring layer 20 and the bump 30 are made of the same material, i.e. aluminum, but are not limited thereto; in different embodiments, the metal wiring layer 20 and the bump 30 can be made of different materials, for example, aluminum for the metal wiring layer 20 and copper for the bump 30. In the present embodiment, the metal wiring layer 20 and the bump 30 are formed in the semiconductor FEOL process and metals commonly used in the semiconductor FEOL processes and more cost effective than gold such as aluminum or copper are used to form the bump 30. The use of metal commonly used in the semiconductor FEOL processes reduces the material costs and is compatible with the other manufacture processes of the semiconductor structure, i.e. the bump 30 is formed using pre-existing wafer manufacturing equipments in semiconductor wafer fabs and can reduce the required equipments and material costs associated with the formation of the bump 30 in the assembly and package factories.

Step A4 includes disposing a metal layer 40 on one side of the bump 30 opposite to the metal wiring layer 20, wherein the activity of the metal layer 40 is smaller than the activity of the bump 30. Specifically, the metal layer 40 is disposed on one side of the bump 30 facing away from the metal wiring layer 20. The metal layer 40 is preferably formed by semiconductor processes or other processes such as electroplating. In the present embodiment, the metal layer 40 is made of gold, but is not limited thereto; in different embodiments, the metal layer 40 can be made of other inert metals. In other words, gold with better electrical conductivity and lower activity is used to form the metal layer 40 on the surface of the bump 30 made of aluminum or copper to reinforce the connection between the bump 30 with other devices and protects the bump 30 from degradation caused by oxidation.

Compared with conventional methods, the method of manufacturing the semiconductor structure of the present invention uses metals that are cheaper and easier to obtain to form the bump 30. In this way, the method of the present invention avoids using more expensive gold to form the bump 30 during the semiconductor BEOL process and thus have the advantages of an integrated semiconductor process and reduced costs, compared with conventional semiconductor processes. Furthermore, the present invention uses smaller amount of gold to form the metal layer 40 on the surface of the bump 30 to reinforce the electrical connection between the die body and other devices and therefore can further reduce costs.

In different embodiments, the metal wiring layer and the bump can be formed using other methods.

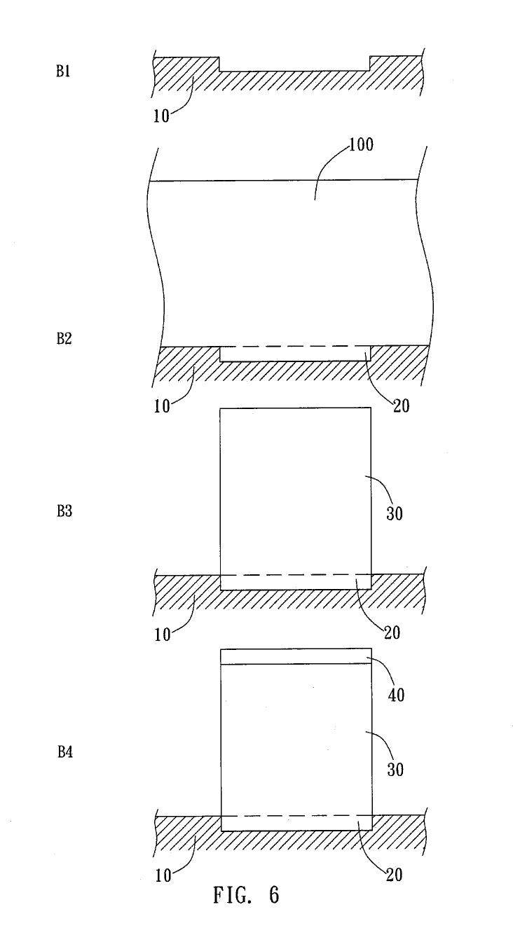

FIG. 6 is a schematic view illustrating another embodiment of the method of manufacturing the semiconductor structure of the present invention. As FIG. 6 shows, step B1 includes forming a plurality of semiconductor device dies on a semiconductor wafer, wherein each of the semiconductor device dies includes a die body 10. Step B1 is similar with step Al and thus is not elaborated here. Step B2 includes depositing a metal material layer 100 with thickness substantially equal to the height of the bump 30 on the die body 10. Step B3 includes processing the metal material layer 100 using the photolithography method and the etching method to form the metal wiring layer 20 and the bump 30. It can be seen from steps B2 and B3 that the metal wiring layer 20 and the bump 30 are formed using the same metal material layer 100, wherein the metal wiring layer 20 and the bump 30 are defined using the photolithography method and the etching method of the semiconductor FEOL processes. Step B4 involves disposing the metal layer 40 on one side of the bump 30 opposite to the metal wiring layer 20, wherein the activity of the metal layer 40 is smaller than the activity of the bump 30. Step B4 of the present embodiment is similar to step A4 illustrated in FIG. 5A and thus is not elaborated here.

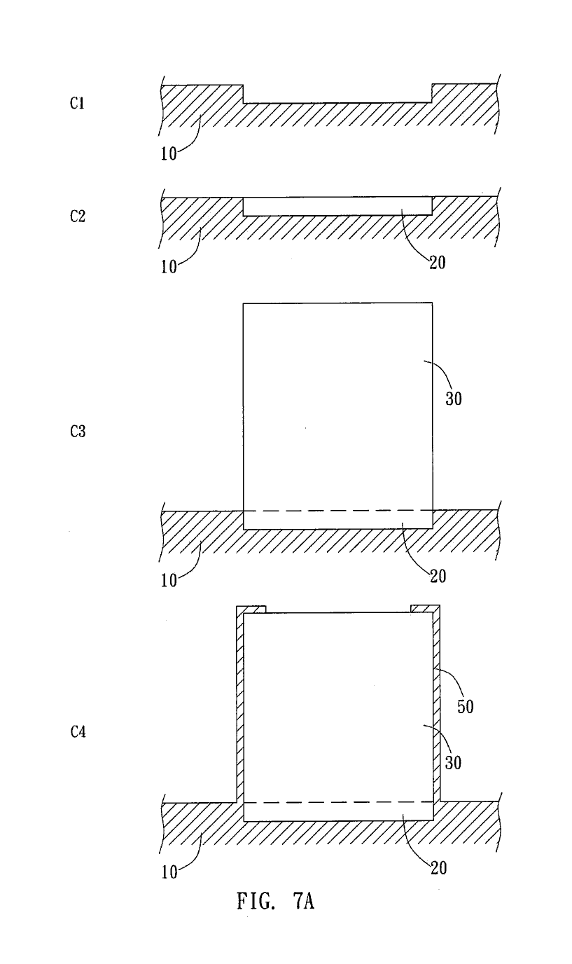

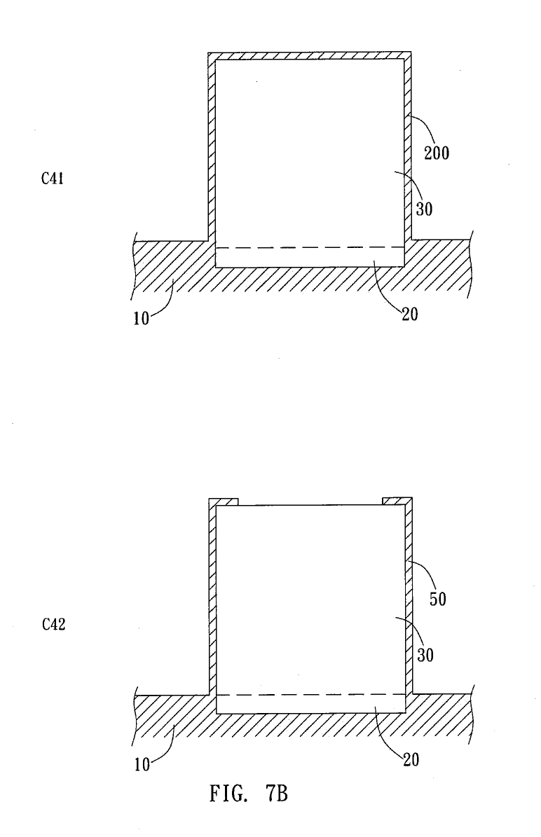

FIG. 7A is a schematic view illustrating another embodiment of the method of manufacturing the semiconductor structure of the present invention. As FIG. 7A shows, step C1 involves forming a plurality of semiconductor device dies on a semiconductor wafer, wherein each of the semiconductor device dies includes a die body 10. However, step C1 is similar to the above-mentioned step A1 and thus is not elaborated here. Step C2 involves forming a metal wiring layer 20 on the die body 10. Step C3 involves forming a bump 30 on the metal wiring layer 20 using semiconductor FEOL processes, wherein the bump 30 protrudes from the surface of the die body 10. The method of forming the metal wiring layer 20 and the bump 30 of the present embodiment can be referred back to the description of steps A2, A3 as well as steps B2, B3 and thus is not elaborated here. In the present embodiment, the method further includes step C4 of forming an insulating layer 50 on a sidewall of the bump 30. In a more preferred embodiment, as FIG. 7B shows, step C4 of forming the insulating layer includes step C41 of conformably depositing an insulating material 200 on the semiconductor wafer including the bump 30 so that the insulating layer 50 can be evenly disposed on the die body 10 and the surface of the bump 30 to have a topography similar to the die body 10 having the protruded bump 30. Step C42 involves etching the insulating material 200 to form the insulating layer 50 on the sidewall of the bump 30 and remove other portions of the insulating material 200 from the surface of the die body 10 and other portions of the bump 30. For instance, the semiconductor FEOL processes for forming spacer can be used to perform anisotropic etching on the insulating material 200 and form the insulating layer 50 on the exposed sidewall of the bump 30 without using the photolithography process. Alternatively, the photolithography process can be used to define the metal layer 40 to be exposed and then use the etching process to remove a portion of the insulating material 200 on the surface of the bump 30 in order to form the insulating layer 50 illustrated in step C4 of FIG. 7A. In the present embodiment, the method of manufacturing the semiconductor structure further includes Step C5 of disposing a metal layer 40 on one side of the metal wiring layer 20 to form a semiconductor structure similar to FIG. 3, wherein the activity of the metal layer 40 is smaller than the activity of the bump 30. The step of disposing the metal layer is similar to steps A4 and B4 described above and thus is not elaborated here.

Specifically, the insulating layer 50 is disposed on the sidewall of the bump 30 and surrounds the bump 30 in order to provide the bump 30 with insulation and thus protection against oxidation. In a more preferred embodiment, the insulating layer 50 extends toward the centre of the top of the bump 30 and covers a portion of the top of the bump 30. In this way, a covering portion of the insulating layer 50 is located between the bump 30 and the metal layer 40 in order to ensure that the connection between the bump 30 and the metal layer 40 are not exposed and therefore not subject to oxidation. However, in different embodiments, the cover portion of the insulating layer 50 can be omitted so that the insulating layer 50 is disposed only on the sidewall of the bump 30. The insulating layer 50 can be made of insulating materials such as silicon nitride, silicon oxide, silicon oxynitride and has noticeable thickness in order to provide the bump 30 with insulation and protection from reaction such as oxidation. Furthermore, the insulating layer 50 disposed on the sidewall of the bump can prevent the adjacent bumps from short-circuit.

The above is a detailed description of the particular embodiments of the invention which is not intended to limit the invention to the embodiment described. It is recognized that modifications within the scope of the invention will occur to a person skilled in the art. Such modifications and equivalents of the invention are intended for inclusion within the scope of this invention.

What is claimed is:

1. A semiconductor structure, comprising:
a semiconductor wafer having a plurality of semiconductor device dies, wherein each of the semiconductor device dies includes:
a die body;
at least one metal wiring layer formed on the die body;
at least one bump formed on the metal wiring layer during a semiconductor front-end-of-line process, the at least one bump protruding from the die body; and
a metal layer disposed on one side of the bump opposite to the metal wiring layer, wherein the activity of the metal layer is smaller than the activity of the bump.

2. The semiconductor structure of claim 1, wherein the semiconductor device die further includes an insulating layer disposed on a sidewall of the bump.

3. The semiconductor structure of claim 2, wherein a portion of the insulating layer is located between the bump and the metal layer.

4. The semiconductor structure of claim 1, wherein a material of the bump includes aluminum.

5. The semiconductor structure of claim 1, wherein a material of the metal layer includes gold.

6. A method of manufacturing a semiconductor structure, comprising steps of:
providing a semiconductor wafer;
forming a plurality of semiconductor device dies on the wafer, wherein each of the semiconductor device dies includes a die body;
forming at least one metal wiring layer on the die body;
forming at least one bump on the metal wiring layer using a semiconductor front-end-of-line process, the bump protruding from the die body; and
disposing a metal layer on one side of the bump opposite to the metal wiring layer, wherein the activity of the metal layer is smaller than the activity of the bump.

7. The method of claim 6, further comprising forming an insulating layer on a sidewall of the bump.

8. The method of claim 7, wherein the step of forming the insulating layer includes conformably depositing an insulating material on the semiconductor wafer including the bump and performing an anisotropic etching on the insulating material to form the insulating layer.

9. The method of claim 6, wherein the step of forming the bump using the semiconductor process includes depositing a layer of metal material with activity greater than the activity of gold on the metal wiring layer using a blanket deposition method and processing the metal wiring layer using a lithography method and an etching method to form the bump on the metal wiring layer.

10. The method of claim 6, wherein the step of forming the metal wiring layer and the bump includes depositing a layer of metal material with a thickness comparable to a height of the bump, performing a lithography process and an etching process on the layer of metal material to form the metal wiring layer and the bump.
